(19) United States
(12) Patent Application Publication
(10) Pub. No.: US 2015/0316804 A1
(43) Pub. Date: Nov. 5, 2015

(54) CONDUCTIVE STRUCTURE, METHOD FOR PRODUCING CONDUCTIVE STRUCTURE, AND DISPLAY DEVICE

(71) Applicant: SHARP KABUSHIKI KAISHA, Osaka-shi, Osaka (JP)

(72) Inventor: Mitsunobu MIYAMOTO, Osaka-shi (JP)

(73) Assignee: Sharp Kabushiki Kaisha, Osaka-shi, Osaka (JP)

(21) Appl. No.: 14/653,954

(22) PCT Filed: Dec. 20, 2013
(86) PCT No.: PCT/JP2013/084181

§ 371 Date: Jun. 19, 2015

(30) Foreign Application Priority Data
Dec. 28, 2012 (JP) 2012-287656

(51) Int. Cl. G02F 1/1368; H01L 27/12

(52) U.S. Cl. CPC G02F 1/1368; H01L 27/1288

(57) ABSTRACT

The present invention provides a conductive structure capable of sufficiently preventing connection failure between two conductive layers regardless of the diameter and depth of a contact hole, a method for producing the conductive structure, and a display device including the conductive structure. The conductive structure of the present invention includes, in the following sequence: a first conductive layer, at least one insulating layer, and a second conductive layer electrically connected to the first conductive layer, the first conductive layer including a protrusion that is disposed in an opening provided in the at least one insulating layer and is connected directly to the second conductive layer.

### TECHNICAL FIELD

The present invention relates to a conductive structure, a method for producing a conductive structure, and a display device. Specifically, the present invention relates to a conductive structure including two conductive layers that are electrically connected via at least one insulating layer disposed therebetween, a method for producing the conductive structure, and a display device including the conductive structure.

### BACKGROUND ART

In order to produce microstructured semiconductor devices or the like, studies have recently been made on a contact hole with a smaller diameter for connecting two conductive layers and on a simplified production process, for example as described below.

A method for producing a semiconductor device has been disclosed (for example, Patent Literature 1) which includes the steps of: (a) forming, in an interlayer insulating film, a pad for connection to a bit line and a capacitor electrode in an upper layer, the interlayer insulating film including, as an uppermost layer, a first insulating film which ensures a sufficiently high selectivity to a second insulating film to be deposited in a second stage; (b) depositing the second insulating film which ensures a sufficiently high selectivity to the first insulating film, and flattening and then etching the second insulating film through a reverse pattern of the bit line as a mask, down to the first insulating film as an etching stopper; (c) filling the pattern with a conductive material which forms the bit line, and then removing the conductive material to form recesses in the second insulating film to form the bit line; (d) depositing a third insulating film which ensures a sufficiently high selectivity to the second insulating film so that the recesses are embedded, and then removing the third insulating film to expose the second insulating film, followed by removing the second insulating film; (e) completely covering the side faces of the bit line by depositing an insulating film of the same kind as the third insulating film and then performing anisotropic etching; and (f) depositing a fourth insulating film which ensures a sufficiently high selectivity to the first and third insulating films, and flattening and then etching the fourth insulating film down to the third and first insulating films as etching stoppers on the bit line and the side face to create a contact hole for forming a capacitor electrode.

### CITATION LIST

### Patent Literature

### Patent Literature 1: JP 2000-183308 A

### SUMMARY OF INVENTION

### Technical Problem

Microstructured semiconductor devices are currently demanded as described above. In the case of conductive structures in which a contact hole is provided to electrically connect two conductive layers with each other, connection failure may occur between the two conductive layers depending on the diameter and depth of the contact hole.

A conventional conductive structure as shown in FIG. 44, for example, will be explained below. FIG. 44 is an explanatory view showing a conventional conductive structure.

A conductive structure 101 in FIG. 44 is disposed on a main surface of a substrate 102. The conductive structure 101 includes a first conductive layer 103 on the substrate 102; an insulating layer 106 that is formed to cover the first conductive layer 103 and includes contact holes (openings) 107a and 107b; and second conductive layers 105a and 105b to be connected to the first conductive layer 103 inside the contact holes 107a and 107b, respectively. The first conductive layer 103 and the second conductive layer 105a are metal films which are usually formed by sputtering. The second conductive layer 105b is a metal film formed of a conductive liquid material.

In order to connect the first conductive layer 103 (metal film) to the second conductive layer 105a (metal film) inside the contact hole 107a in FIG. 44, usually the second conductive layer 105a is formed by sputtering to fill the contact hole 107a, so that the second conductive layer 105a is connected to the first conductive layer 103. However, if the contact hole 107a has a small diameter or is deep, the contact hole 107a may not be sufficiently filled with the second conductive layer 105a. In such a case, for example, connection failure may occur between the first conductive layer 103 and the second conductive layer 105a, and the interconnection resistance between the first conductive layer 103 and the second conductive layer 105a may increase. Such a conductive structure does not sufficiently work and has poor reliability.

In connecting the first conductive layer 103 (metal film) to the second conductive layer 105b (conductive liquid material) inside the contact hole 107b in FIG. 44, usually air 26 may be trapped between the first conductive layer 103 and the second conductive layer 105b as shown in FIG. 44. Thus, connection failure may occur between the first conductive layer 103 and the second conductive layer 105b.

In FIG. 44, two or more insulating layers (for example, insulating layer 106) are stacked between the first conductive layer 103 and the second conductive layer 105a. For reducing the number of steps of creating a contact hole, a contact hole may be created through the stacked two or more insulating layers. In such a case, the depth of the contact hole is increased by the stacked insulating layers, which may cause connection failure between the first conductive layer 103 and the second conductive layer 105a.

As mentioned above, a conventional conductive structure which includes a contact hole to electrically connect two conductive layers may have a problem of connection failure between the two conductive layers depending on the diameter and depth of the contact hole.

Patent Literature 1 discloses a method for producing a semiconductor device. In accordance with the method, a contact hole is stably formed between tiny bit lines, and the production steps are reduced. The invention of Patent Literature 1 features a technique of embedding the tiny contact hole with a conductive material. Unfortunately, the contact hole may not be readily embedded with the conductive material depending on its diameter and depth. Thus, the invention needs improvement to solve the aforementioned problem.

The present invention was made in consideration of the aforementioned current state, and aims to provide a conductive structure capable of sufficiently preventing connection failure between two conductive layers regardless of the diameter and depth of a contact hole, a method for producing the conductive structure, and a display device including the conductive structure.

### Solution to Problem

The present inventors made various studies to achieve a conductive structure capable of sufficiently preventing connection failure between two conductive layers regardless of the diameter and depth of a contact hole, and they focused on improving the shape of a conductive layer which is firstly formed among the two conductive layers. As a result, they found that, if the first-formed conductive layer includes a protrusion in a contact hole, and the protrusion is connected directly to a later-formed conductive layer, then connection failure between the two conductive layers can be sufficiently prevented regardless of the diameter and depth of the contact hole. Accordingly, the inventors succeeded to solve the above problem, thereby completing the present invention.

That is, one aspect of the present invention may be a conductive structure including, in the following sequence: a first conductive layer, at least one insulating layer, and a second conductive layer electrically connected to the first conductive layer, the first conductive layer including a protrusion that is disposed in an opening provided in the at least one insulating layer and is connected directly to the second conductive layer.

The opening provided in the at least one insulating layer and the protrusion will be described referring to, for example, a conductive structure 1 shown in FIG. 1. FIG. 1 is an explanatory view showing one example of the conductive structure of the present invention. As shown in FIG. 1, the conductive structure 1 includes, in the following sequence: a first conductive layer 3, an insulating layer 6, and a second conductive layer 5 electrically connected to the first conductive layer 3, which are formed on or above a main surface of a substrate 2. The opening provided in the at least one insulating layer refers to an opening like, for example, an opening 7 in the insulating layer 6 provided to connect the first conductive layer 3 to the second conductive layer 5, and corresponds to the aforementioned contact hole. The protrusion refers to a protrusion like a protrusion 4 of the first conductive layer 3 disposed in the opening 7 of the insulating layer 6. The protrusion 4 is connected directly to the second conductive layer 5. In FIG. 1, the protrusion 4 contacts an inner wall surface of the opening 7. The diameter and depth of the contact hole (opening) are indicated by R and D, respectively, in FIG. 1.

The conductive structure in the above one aspect of the present invention is not especially limited by other components.

The present inventors made various studies to achieve a method for producing a conductive structure capable of sufficiently preventing connection failure between two conductive layers regardless of the diameter and depth of a contact hole, and they focused on a method for producing a conductive layer which has a suitable shape and is firstly formed among the two conductive layers. As a result, they found that, if the conductive layer which is firstly formed is formed on a side wall of a photoresist disposed at a site where the contact hole is provided, and at least a portion of the conductive layer which is firstly formed on the side wall of the photoresist is connected directly to the conductive layer which is later formed, then connection failure between the two conductive layers can be sufficiently prevented regardless of the diameter and depth of the contact hole. Accordingly, the inventors succeeded to solve the above problem, thereby completing the present invention.

That is, one aspect of the present invention may be a method for producing a conductive structure including, in the following sequence, a first conductive layer, at least one insulating layer, and a second conductive layer electrically connected to the first conductive layer, the method including the steps of:

(1) forming, on a main surface of a substrate, a photoresist including a side wall that is perpendicular to the main surface of the substrate,

(2) forming a film for the first conductive layer to cover the photoresist, and

(3) anisotropically etching the film for the first conductive layer so that at least the portion of the first conductive layer on the side wall of the photoresist remains.

The method for producing a conductive structure in the above one aspect of the present invention is not especially limited and may include other steps.

One aspect of the present invention may be a display device including the conductive structure.

The display device in the above one aspect of the present invention is not especially limited by other components, and may appropriately include other components which are usually used for display devices.

### Advantageous Effects of Invention

In aspects, the present invention can provide a conductive structure capable of sufficiently preventing connection failure between two conductive layers regardless of the diameter and depth of a contact hole, a method for producing the conductive structure, and a display device including the conductive structure.

### BRIEF DESCRIPTION OF DRAWINGS

FIG. 1 is an explanatory view showing one example of the conductive structure of the present invention.

FIG. 2 is a schematic plan view showing a pixel portion of a thin film transistor array substrate which includes a conductive structure of Embodiment 1.

FIG. 3 shows a schematic cross-sectional view at a-a′ line in FIG. 2.

FIG. 4 is a schematic plan view showing a state after the step of forming a gate insulator in Embodiment 1.

FIG. 5 shows schematic cross-sectional views at A-A′ line and B-B′ line in FIG. 4.

FIG. 6 is a schematic plan view showing a state after the step of forming a thick film photoresist in Embodiment 1.

FIG. 7 shows schematic cross-sectional views at A-A′ line and B-B′ line in FIG. 6.

FIG. 8 is a schematic plan view showing a state after the step of forming a conductive film (film for the first conductive layer) in Embodiment 1.

FIG. 9 shows schematic cross-sectional views at A-A′ line and B-B′ line in FIG. 8.

FIG. 10 is a schematic plan view showing a state after the step of forming a photoresist for patterning in Embodiment 1.

FIG. 11 shows schematic cross-sectional views at A-A′ line and B-B′ line in FIG. 10.

FIG. 12 is a schematic plan view showing a state after the step of etching a conductive film (film for the first conductive layer) in Embodiment 1.

FIG. 13 shows schematic cross-sectional views at A-A′ line and B-B′ line in FIG. 12.

FIG. 14 is a schematic plan view showing a state after the step of forming a protection film in Embodiment 1.

FIG. 15 shows schematic cross-sectional views at A-A′ line and B-B′ line in FIG. 14.

FIG. 16 is a schematic plan view showing a state after the step of forming a flat film in Embodiment 1.

FIG. 17 shows schematic cross-sectional views at A-A′ line and B-B′ line in FIG. 16.

FIG. 18 is a schematic plan view showing a state after the step of forming a conductive film (film for the second conductive layer) in Embodiment 1.

FIG. 19 shows schematic cross-sectional views at A-A′ line and B-B′ line in FIG. 18.

FIG. 20 is a schematic plan view showing a connection terminal of a thin film transistor array substrate which includes a conductive structure of Embodiment 2.

FIG. 21 shows a schematic cross-sectional view at b-b′ line in FIG. 20.

FIG. 22 is a schematic plan view showing a substrate used in the production of a conductive structure of Embodiment 2.

FIG. 23 shows schematic cross-sectional views at A-A′ line and B-B′ line in FIG. 22.

FIG. 24 is a schematic plan view showing a state after the step of forming a thick film photoresist in Embodiment 2.

FIG. 25 shows schematic cross-sectional views at A-A′ line and B-B′ line in FIG. 24.

FIG. 26 is a schematic plan view showing a state after the step of forming a conductive film (film for the first conductive layer) in Embodiment 2.

FIG. 27 shows schematic cross-sectional views at A-A′ line and B-B′ line in FIG. 26.

FIG. 28 is a schematic plan view showing a state after the step of forming a photoresist for patterning in Embodiment 2.

FIG. 29 shows schematic cross-sectional views at A-A′ line and B-B′ line in FIG. 28.

FIG. 30 is a schematic plan view showing a state after the step of etching a conductive film (film for the first conductive layer) in Embodiment 2.

FIG. 31 shows schematic cross-sectional views at A-A′ line and B-B′ line in FIG. 30.

FIG. 32 is a schematic plan view showing a state after the photoresist-asking step in Embodiment 2.

FIG. 33 shows schematic cross-sectional views at A-A′ line and B-B′ line in FIG. 32.

FIG. 34 is a schematic plan view showing a state after the step of forming an insulating film in Embodiment 2.

FIG. 35 shows schematic cross-sectional views at A-A′ line and B-B′ line in FIG. 34.

FIG. 36 is a schematic plan view showing a state after the step of forming a conductive film (film for the second conductive layer) in Embodiment 2.

FIG. 37 shows schematic cross-sectional views at A-A′ line and B-B′ line in FIG. 36.

FIG. 38 is a schematic perspective view showing a liquid crystal display device which includes a conductive structure of Embodiment 3.

FIG. 39 is a schematic perspective view showing a liquid crystal display device which includes a conductive structure of Embodiment 4.

FIG. 40 is a schematic plan view showing a pixel portion of a thin film transistor array substrate which includes a conductive structure of Comparative Embodiment 1.

FIG. 41 shows a schematic cross-sectional view at c-c′ line in FIG. 40.

FIG. 42 is a schematic plan view showing a connection terminal of a thin film transistor array substrate which includes a conductive structure of Comparative Embodiment 2.

FIG. 43 shows a schematic cross-sectional view at d-d′ line in FIG. 42.

FIG. 44 is an explanatory view showing a conventional conductive structure.

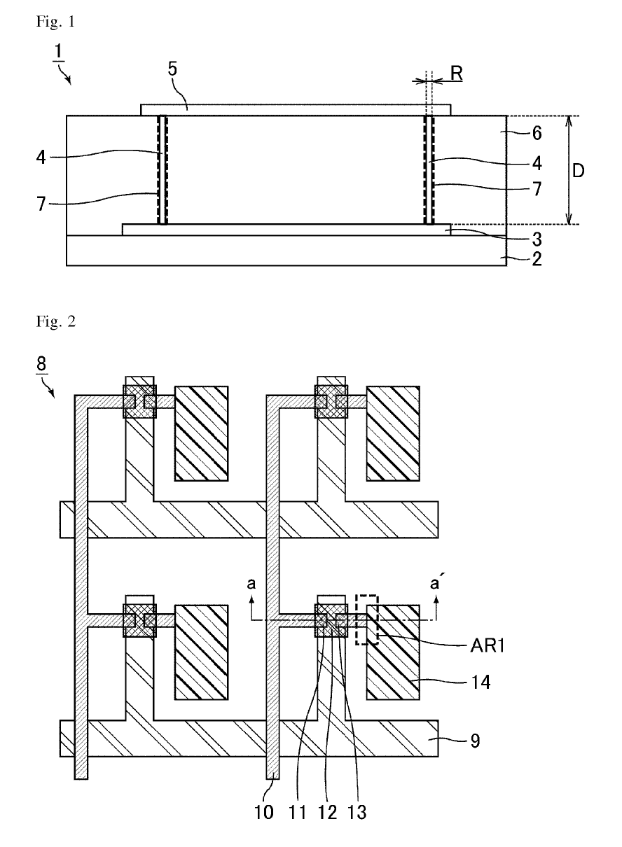

### DESCRIPTION OF EMBODIMENTS

Preferable aspects of the conductive structure of the present invention will be described below.

In one aspect of the conductive structure of the present invention, the first conductive layer may serve as a drain electrode, and the second conductive layer may serve as a pixel electrode.

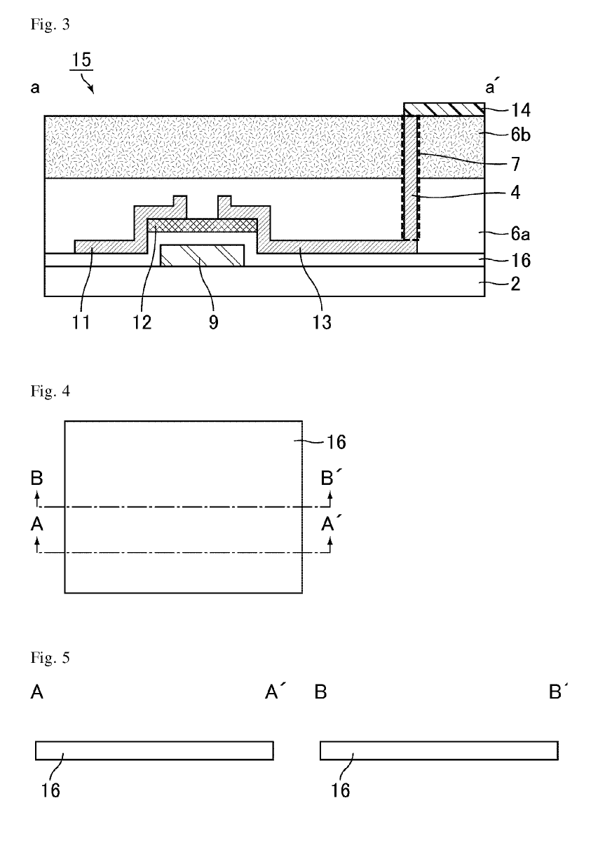

The conductive structure with such features can be used to connect a drain electrode to a pixel electrode in a thin film transistor array substrate including a thin film transistor element. In the case where, for example in a thin film transistor element 15 shown in FIG. 3, a drain electrode 13 includes a protrusion 4 that is disposed in an opening 7 provided in a protection film 6a and a flat film 6b (each corresponding to the at least one insulating layer), and the protrusion 4 is connected directly to a pixel electrode 14, connection failure between the drain electrode 13 and the pixel electrode 14 can be sufficiently prevented regardless of the diameter and depth of the opening 7.

In one aspect of the conductive structure of the present invention, the first conductive layer may serve as a terminal for connection to a source driver, and the second conductive layer may serve as a source bus line.

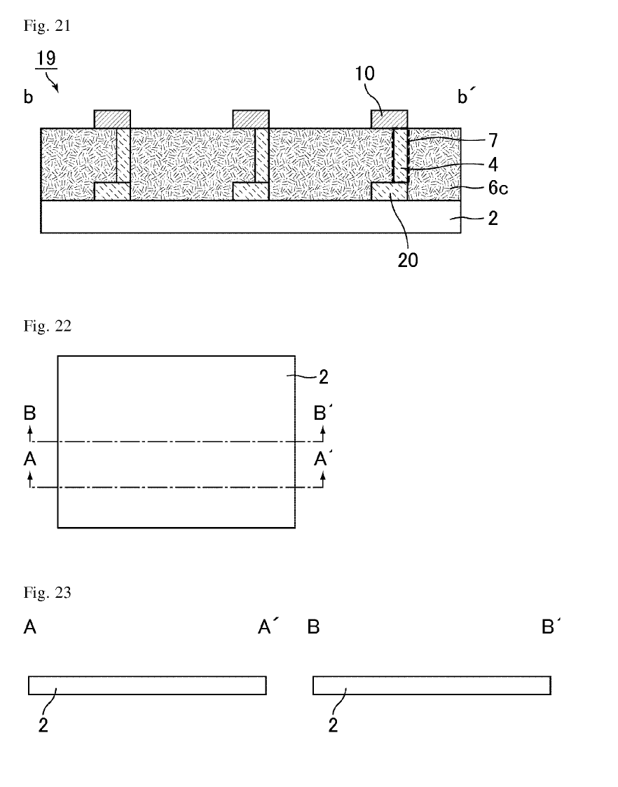

The conductive structure with such features can be used to connect a terminal for connection to a source driver to a source bus line in a thin film transistor array substrate including a thin film transistor element. In the case where, for example in a connection terminal 19 shown in FIG. 21, a terminal 20 for connection to a source driver includes a protrusion 4 that is disposed in an opening 7 provided in an insulating film 6c (corresponding to the at least one insulating layer), and the protrusion 4 is connected directly to a source bus line 10, connection failure between the terminal 20 for connection to a source driver and the source bus line 10 can be sufficiently prevented regardless of the diameter and depth of the opening 7.

In one aspect of the conductive structure of the present invention, the first conductive layer may serve as a pixel electrode; the second conductive layer may serve as a counter electrode; and the at least one insulating layer may include a liquid crystal layer.

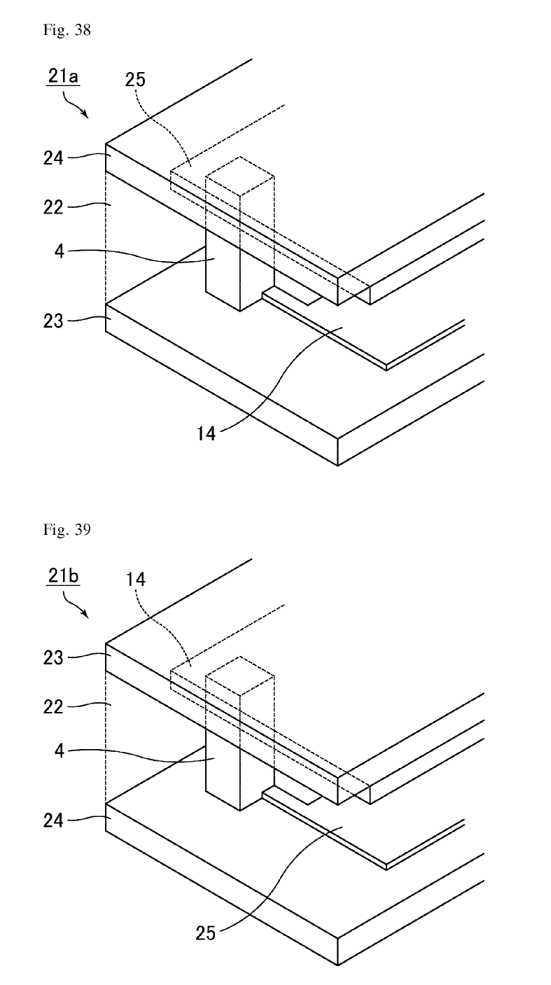

In this aspect, the conductive structure can be used to connect a pixel electrode of a thin film transistor array substrate to a counter electrode of a counter substrate (for example, color filter substrate) which faces the thin film transistor array substrate in a liquid crystal display device. Through the conductive structure, signals supplied from the thin film transistor array substrate can be transmitted to the counter substrate. In the case where, for example in a liquid crystal display device 21a shown in FIG. 38, a pixel electrode 14, which is disposed on the outermost surface of a thin film transistor array substrate 23 on the counter substrate 24 side, includes a protrusion 4 that is disposed in an insulating layer including a liquid crystal layer 22, and the protrusion 4 is connected directly to a counter electrode 25 provided in the counter substrate 24, connection failure between the pixel electrode 14 and the counter electrode 25 can be sufficiently prevented. Further, this aspect allows for suitable connection between the pixel electrode 14 and the counter electrode 25 without using conductive materials such as conductive paste or conductive beads which are usually used to electrically connect the pixel electrode 14 to the counter electrode 25.

In one aspect of the conductive structure of the present invention, the first conductive layer may serve as a counter electrode, the second conductive layer may serve as a pixel electrode, and the at least one insulating layer may include a liquid crystal layer.

In this aspect, the conductive structure can be used to connect a pixel electrode of a thin film transistor array substrate to a counter electrode of a counter substrate which faces the thin film transistor array substrate in a liquid crystal display device. Through the conductive structure, signals supplied from the thin film transistor array substrate can be transmitted to the counter substrate. In the case where, for example in a liquid crystal display device 21b shown in FIG. 39, a counter electrode 25 provided in a counter substrate 24 includes a protrusion 4 that is disposed in an insulating layer including a liquid crystal layer 22, and the protrusion 4 is connected directly to a pixel electrode 14 which is disposed on the outermost surface of a thin film transistor array substrate 23 on the counter substrate 24 side, connection failure between the counter electrode 25 and the pixel electrode 14 can be sufficiently prevented. Further, this aspect allows for suitable connection between the counter electrode 25 and the pixel electrode 14 without using conductive materials such as conductive paste or conductive beads which are usually used to electrically connect the counter electrode 25 to the pixel electrode 14.

The aforementioned aspects of the conductive structure of the present invention may be employed in appropriate combination as long as the combination is not beyond the spirit of the present invention.

Next, preferable aspects of the method for producing a conductive structure of the present invention will be described below.

In one aspect of the method for producing a conductive structure of the present invention, the at least one insulating layer may include a first insulating layer and a second insulating layer, and the step (3) may be followed by the steps of:

(4) forming the first insulating layer to cover the first conductive layer and then creating an opening in the first insulating layer to expose the first conductive layer at a portion to be connected to the second conductive layer,

(5) forming the second insulating layer to cover the first conductive layer and the first insulating layer and then creating an opening in the second insulating layer to expose the first conductive layer at the portion to be connected to the second conductive layer, and

(6) forming the second conductive layer on the side opposite to the substrate and on or above the first conductive layer, the first insulating layer, and the second insulating layer, so that the second conductive layer is connected to the exposed portion of the first conductive layer.

The method with such features allows for production of a structure in which the first conductive layer includes a protrusion that is disposed in an opening provided in the first and second insulating layers, and the protrusion is connected directly to the second conductive layer. Thus, a method for producing a conductive structure can be provided which sufficiently prevents connection failure between the first conductive layer and the second conductive layer regardless of the diameter and depth of the opening. The step of creating an opening in the first insulating layer preferably includes etching of the first insulating layer. The step of creating an opening in the second insulating layer preferably includes ashing of the second insulating layer.

In one aspect of the method for producing a conductive structure of the present invention, the at least one insulating layer may include a third insulating layer, and the step (3) may be followed by the steps of:

(7) removing the photoresist,

(8) forming the third insulating layer to cover the first conductive layer and then creating an opening in the third insulating layer to expose the first conductive layer at a portion to be connected to the second conductive layer, and

(9) forming the second conductive layer on the side opposite to the substrate and on or above the first conductive layer and the third insulating layer, so that the second conductive layer is connected to the exposed portion of the first conductive layer.

The method with such features allows for production of a structure in which the first conductive layer includes a protrusion that is disposed in an opening provided in the third insulating layer, and the protrusion is connected directly to the second conductive layer. Thus, a method for producing a conductive structure can be provided which sufficiently prevents connection failure between the first conductive layer and the second conductive layer regardless of the diameter and depth of the opening. The step of removing the photoresist preferably includes ashing of the photoresist. The step of creating an opening in the third insulating layer preferably includes etching of the third insulating layer.

In one aspect of the method for producing a conductive structure of the present invention, the step (3) may be followed by the step of:

(10) bonding the substrate on or above which the first conductive layer is formed and a counter substrate including the second conductive layer so that the first conductive layer is connected to the second conductive layer.

The method with such features allows for production of a structure in which the first conductive layer includes a protrusion that is disposed in an opening provided in the at least one insulating layer (for example, liquid crystal layer) which is sandwiched between the substrate and the counter substrate, and the protrusion is connected directly to the second conductive layer. Thus, a method for producing a conductive structure can be provided which sufficiently prevents connection failure between the first conductive layer and the second conductive layer regardless of the diameter and depth of the opening.

In one aspect of the method for producing a conductive structure of the present invention, the first conductive layer may serve as a drain electrode, and the second conductive layer may serve as a pixel electrode.

The method with such features allows for connection between a drain electrode and a pixel electrode in a thin film transistor array substrate including a thin film transistor element. In the case where, for example in a thin film transistor element 15 shown in FIG. 3, a drain electrode 13 includes a protrusion 4 that is disposed in an opening 7 provided in a protection film 6a (corresponding to the first insulating layer) and a flat film 6b (corresponding to the second insulating layer), and the protrusion 4 is connected directly to a pixel electrode 14, connection failure between the drain electrode 13 and the pixel electrode 14 can be sufficiently prevented regardless of the diameter and depth of the opening 7.

In one aspect of the method for producing a conductive structure of the present invention, the first conductive layer may serve as a terminal for connection to a source driver, and the second conductive layer may serve as a source bus line.

The method with such features allows for connection between a terminal for connection to a source driver and a source bus line in a thin film transistor array substrate including a thin film transistor element. In the case where, for example in a connection terminal 19 shown in FIG. 21, a terminal 20 for connection to a source driver includes a protrusion 4 that is disposed in an opening 7 provided in an insulating film 6c (corresponding to the third insulating layer), and the protrusion 4 is connected directly to a source bus line 10, connection failure between the terminal 20 for connection to a source driver and the source bus line 10 can be sufficiently prevented regardless of the diameter and depth of the opening 7.

In one aspect of the method for producing a conductive structure of the present invention, the first conductive layer may serve as a pixel electrode, the second conductive layer may serve as a counter electrode, and the at least one insulating layer may include a liquid crystal layer.

A conductive structure produced by the method of this aspect can be used to connect a pixel electrode of a thin film transistor array substrate to a counter electrode of a counter substrate which faces the thin film transistor array substrate in a liquid crystal display device. Through the conductive structure, signals supplied from the thin film transistor array substrate can be transmitted to the counter substrate. In the case where, for example in a liquid crystal display device 21a shown in FIG. 38, a pixel electrode 14, which is disposed on the outermost surface of a thin film transistor array substrate 23 on the counter substrate 24 side, is formed to include a protrusion 4 that is disposed in an insulating layer including a liquid crystal layer 22, and the protrusion 4 is connected directly to a counter electrode 25 provided in the counter substrate 24, connection failure between the pixel electrode 14 and the counter electrode 25 can be sufficiently prevented. Further, this aspect allows for suitable connection between the pixel electrode 14 and the counter electrode 25 without using conductive materials such as conductive paste or conductive beads which are usually used to electrically connect the pixel electrode 14 to the counter electrode 25.

In one aspect of the method for producing a conductive structure of the present invention, the first conductive layer may serve as a counter electrode, the second conductive layer may serve as a pixel electrode, and the at least one insulating layer may include a liquid crystal layer.

A conductive structure produced by the method of this aspect can be used to connect a pixel electrode of a thin film transistor array substrate to a counter electrode of a counter substrate which faces the thin film transistor array substrate in a liquid crystal display device. Through the conductive structure, signals supplied from the thin film transistor array substrate can be transmitted to the counter substrate. In the case where, for example in a liquid crystal display device 21b shown in FIG. 39, a counter electrode 25 provided in a counter substrate 24 includes a protrusion 4 that is disposed in an insulating layer including a liquid crystal layer 22, and the protrusion 4 is connected directly to a pixel electrode 14 which is disposed on the outermost surface of a thin film transistor array substrate 23 on the counter substrate 24 side, connection failure between the counter electrode 25 and the pixel electrode 14 can be sufficiently prevented. Further, this aspect allows for suitable connection between the counter electrode 25 and the pixel electrode 14 without using conductive materials such as conductive paste or conductive beads which are usually used to electrically connect the counter electrode 25 to the pixel electrode 14.

Preferable aspects of conductive structures obtained by the method for producing a conductive structure of the present invention are the same as the preferable aspects of the conductive structure of the present invention.

The aforementioned aspects of the method for producing a conductive structure of the present invention may be employed in appropriate combination as long as the combination is not beyond the spirit of the present invention.

Preferable aspects of the display device of the present invention may include the conductive structure of the present invention according to the aforementioned preferable embodiment(s). Such aspects can reduce the diameter of the opening, thereby achieving a display device with high resolution.

The aforementioned aspects of the display device of the present invention may be employed in appropriate combination as long as the combination is not beyond the spirit of the present invention.

The present invention will be described in more detail referring to the drawings in the following embodiments, but is not limited to these embodiments. The below-mentioned modes of the embodiments may be employed in appropriate combination as long as the combination is not beyond the spirit of the present invention.

The conductive structures of the embodiments each basically include in sequence a first conductive layer, at least one insulating layer, and a second conductive layer electrically connected to the first conductive layer.

The present invention is applicable to any conductive structure which is provided with an opening (contact hole) for electrically connecting two conductive layers. The following will describe a conductive structure in a thin film transistor array substrate including a thin film transistor element, and a conductive structure in a liquid crystal display device.

### Embodiment 1

In Embodiment 1, the conductive structure of the present invention is used to connect a drain electrode to a pixel electrode in a thin film transistor array substrate including a thin film transistor element.

The conductive structure of Embodiment 1 will be described referring to FIG. 2 and FIG. 3.

FIG. 2 is a schematic plan view showing a pixel portion of a thin film transistor array substrate which includes a conductive structure of Embodiment 1. In a pixel portion 8 shown in FIG. 2, a voltage supplied from a source bus line 10 is applied through a source electrode 11, a semiconductor layer 12, and a drain electrode 13 to a pixel electrode 14 at the timing when a pixel is selected by a gate bus line 9.

FIG. 3 shows a schematic cross-sectional view at a-a′ line in FIG. 2. As shown in FIG. 3, a thin film transistor element 15 of the thin film transistor array substrate includes a substrate 2 (for example, glass substrate); a gate bus line 9 provided on the main surface of the substrate 2; agate insulator 16 provided in a manner of covering the gate bus line 9; a semiconductor layer 12 provided on apart of the gate insulator 16 at a position overlapped with the gate bus line 9 in a plan view of the main surface of the substrate 2; a source electrode 11 provided on a part of the gate insulator 16 and a part of the semiconductor layer 12 on the side opposite to the substrate 2 side of the gate insulator 16 and the semiconductor layer 12; a drain electrode 13 provided on a part of the gate insulator 16 and a part of the semiconductor layer 12 on the side opposite to the substrate 2 side of the gate insulator 16 and the semiconductor layer 12; a protection film 6a provided in a manner of covering the gate insulator 16, the semiconductor layer 12, the source electrode 11, and the drain electrode 13; a flat film 6b provided on the protection film 6a on the side opposite to the substrate 2 side of the protection film 6a; and a pixel electrode 14 provided on the drain electrode 13 and the flat film 6b to be in contact with an exposed portion of the drain electrode 13 on the side opposite to the substrate 2 side of the drain electrode 13 and the flat film 6b.

Moreover, as shown in FIG. 3, the drain electrode 13 includes a protrusion 4 that is disposed in an opening 7 provided in the protection film 6a and the flat film 6b. The protrusion 4 is connected directly to the pixel electrode 14. Thus, connection failure between the drain electrode 13 and the pixel electrode 14 can be sufficiently prevented regardless of the diameter and depth of the opening 7. In FIG. 3, the protrusion 4 is in contact with an inner wall surface of the opening 7.

The semiconductor layer 12 may have any structure but preferably includes an oxide semiconductor. The oxide semiconductor has a higher mobility and more uniform characteristics than an amorphous silicon. Thus, a thin film transistor element including the oxide semiconductor can behave faster, has a higher driving frequency, and requires a smaller proportion in one pixel than a thin film transistor element including an amorphous silicon. Such a thin film transistor element including the oxide semiconductor can be suitably used for driving next generation display devices with a higher definition. Oxide semiconductor films, which are produced by a simpler process than polycrystal silicon films, are advantageously applicable to devices which require a film to be formed in a large area. The oxide semiconductor may contain, for example, a composition including indium (In), gallium (Ga), zinc (Zn), and oxygen (O), a composition including indium (In), tin (Tin), zinc (Zn), and oxygen (O), or a composition including indium (In), aluminum (Al), zinc (Zn), and oxygen (O).

The drain electrode 13 preferably includes a metal film. The metal film preferably contains titanium (Ti), aluminum (Al), or the like. The thickness of the drain electrode 13 is not particularly limited, and is preferably 300 nm or more but 500 nm or less.

The protection film 6a is preferably an inorganic insulating film. The thickness of the protection film 6a is not particularly limited, and is preferably 400 nm or more but 600 nm or less.

The flat film 6b is preferably an organic insulating film. The thickness of the flat film 6b is not particularly limited, and is preferably 1.5 μm or more but 2.5 μm or less.

Indium tin oxide (ITO) or the like is preferably used for the pixel electrode 14. The thickness of the pixel electrode 14 is not particularly limited, and is preferably 80 nm or more but 150 nm or less.

The diameter of the opening 7 is not particularly limited, and is preferably 1.0 μm or larger but 4.0 μm or smaller. The conductive structure of Embodiment 1 is particularly suitably used in the case where the opening 7 has a diameter of 2.0 μm or smaller. The depth (depth perpendicular to the main surface of the substrate 2) of the opening 7 is not particularly limited. The conductive structure of Embodiment 1 is particularly suitably used in the case where the opening 7 has a depth of 600 nm or more. The shape of the opening 7 is not particularly limited. The opening 7 may have a shape other than a columnar shape, for example, a rectangular parallelepiped shape. The diameter of the opening 7 may not only be the diameter of a circle or an ellipse but also be the length of a side of a square or a rectangle.

The height (height perpendicular to the main surface of the substrate 2) of the protrusion 4 is not particularly limited, and is preferably 0.6 μm or more but 4.0 μm or less. Although the height of the protrusion 4 is depicted to be the same as the depth of the opening 7 in FIG. 3, the height of the protrusion 4 may be different from the depth of the opening 7. The height of the protrusion 4 is preferably the same as the depth of the opening 7. The height of the protrusion 4 may be smaller or greater than the depth of the opening 7 as long as the protrusion 4 can be connected directly to the pixel electrode 14. The shape of the protrusion 4 is not particularly limited. The protrusion 4 may have a shape other than a columnar shape, for example, a rectangular parallelepiped shape.

The drain electrode 13 and the pixel electrode 14 correspond to the first conductive layer and the second conductive layer, respectively, in one aspect of the present invention. The protection film 6a and the flat film 6b individually correspond to the at least one insulating layer in one aspect of the present invention. The opening 7 provided in the protection film 6a and the flat film 6b corresponds to the opening provided in the at least one insulating layer in one aspect of the present invention. The protrusion 4 corresponds to the protrusion in one aspect of the present invention.

The following will describe the method for producing a conductive structure of Embodiment 1. The conductive structure is used to connect the drain electrode 13 to the pixel electrode 14 at a site AR1 in FIG. 2.

The method for producing a conductive structure of Embodiment 1 includes a step of forming a gate insulator, a step of forming a thick film photoresist, a step of forming a conductive film (film for the first conductive layer), a step of forming a photoresist for patterning, a step of etching a conductive film (film for the first conductive layer), a step of forming a protection film, a step of forming a flat film, and a step of forming a conductive film (film for the second conductive layer).

### (Step of Forming a Gate Insulator)

The step of forming a gate insulator in Embodiment 1 will be described referring to FIG. 4 and FIG. 5. FIG. 4 is a schematic plan view showing a state after the step of forming a gate insulator in Embodiment 1. FIG. 5 shows schematic cross-sectional views at A-A′ line and B-B′ line in FIG. 4. The schematic cross-sectional views at different lines, A-A′ line and B-B′ line, shown in FIG. 5 are exemplary views arranged to be adjacent to each other on the same horizontal plane. This applies to other schematic cross-sectional views as well. As shown in FIG. 4 and FIG. 5, the gate insulator 16 is formed on the main surface of a glass substrate (corresponding to the substrate 2 in FIG. 3).

### (Step of Forming a Thick Film Photoresist)

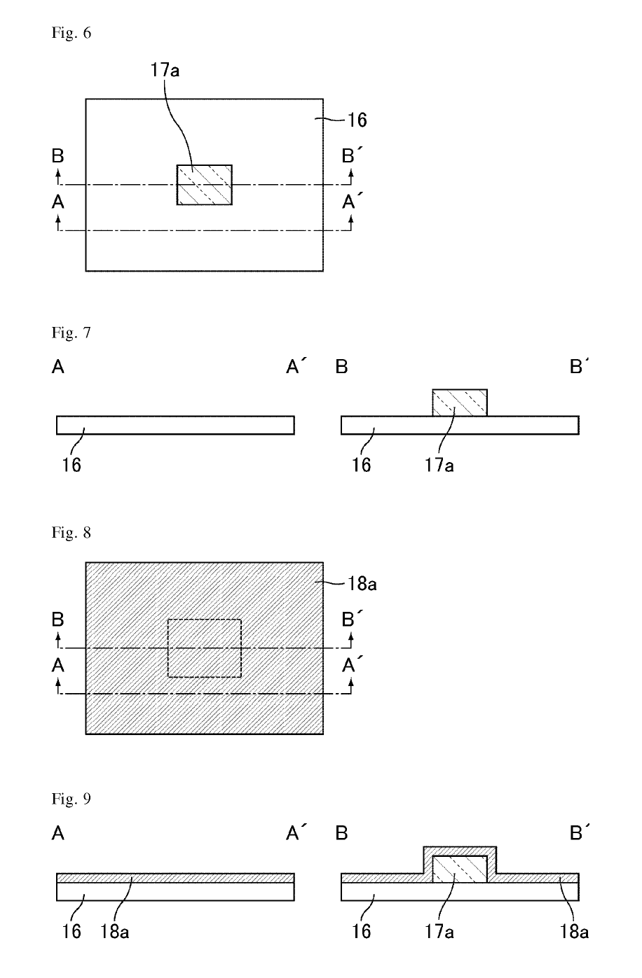

The step of forming a thick film photoresist in Embodiment 1 will be described referring to FIG. 6 and FIG. 7. FIG. 6 is a schematic plan view showing a state after the step of forming a thick film photoresist in Embodiment 1. FIG. 7 shows schematic cross-sectional views at A-A′ line and B-B′ line in FIG. 6. As shown in FIG. 6 and FIG. 7, a photoresist 17a is formed through application, exposure to light, development, and baking, on a part of the gate insulator 16 on the side opposite to the glass substrate side of the gate insulator 16 to include a side wall that is perpendicular to the main surface of the glass substrate. The baking is performed to cure the photoresist. Desolvation of the photoresist 17a is suppressed, and the shape of the photoresist 17a is maintained due to subsequent film formation or the like on the photoresist 17a. The thickness of the photoresist 17a is not particularly limited, and is preferably 1.2 μm or more but 4.0 μm or less.

### (Step of Forming a Conductive Film (Film for the First Conductive Layer))

The step of forming a conductive film (film for the first conductive layer) in Embodiment 1 will be described referring to FIG. 8 and FIG. 9. FIG. 8 is a schematic plan view showing a state after the step of forming a conductive film (film for the first conductive layer) in Embodiment 1. FIG. 9 shows schematic cross-sectional views at A-A′ line and B-B′ line in FIG. 8. As shown in FIG. 8 and FIG. 9, a conductive film 18a is formed by sputtering to cover the gate insulator 16 and the photoresist 17a. The conductive film 18a is to be made into the drain electrode 13 through subsequent steps. The conductive film 18a preferably includes a metal film. The metal film preferably contains titanium (Ti), aluminum (Al), or the like. The thickness of the conductive film 18a is not particularly limited, and is preferably 300 nm or more but 500 nm or less.

### (Step of Forming a Photoresist for Patterning)

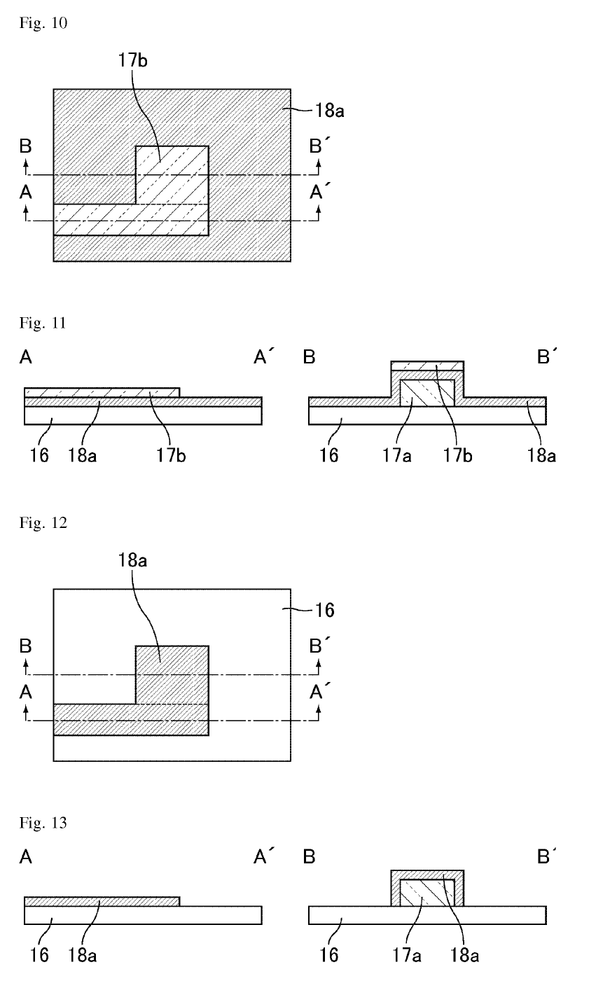

The step of forming a photoresist for patterning in Embodiment 1 will be described referring to FIG. 10 and FIG. 11. FIG. 10 is a schematic plan view showing a state after the step of forming a photoresist for patterning in Embodiment 1. FIG. 11 shows schematic cross-sectional views at A-A′ line and B-B′ line in FIG. 10. As shown in FIG. 10 and FIG. 11, a photoresist 17b is formed by photolithography on a part of the conductive film 18a on the side opposite to the glass substrate side of the conductive film 18a so that the conductive film 18a is patterned into the shape of the drain electrode 13.

### (Step of Etching a Conductive Film (Film for the First Conductive Layer))

The step of etching a conductive film (film for the first conductive layer) in Embodiment 1 will be described referring to FIG. 12 and FIG. 13. FIG. 12 is a schematic plan view showing a state after the step of etching a conductive film (film for the first conductive layer) in Embodiment 1. FIG. 13 shows schematic cross-sectional views at A-A′ line and B-B′ line in FIG. 12. As shown in FIG. 12 and FIG. 13, a part of the conductive film 18a not overlapped with the photoresist 17b in a plan view of the main surface of the glass substrate is removed by anisotropic dry etching. Then, the photoresist 17b is removed by ashing. As a result, the conductive film 18a remains on the upper side and side wall of the photoresist 17a so that a pattern of the drain electrode 13 is formed.

### (Step of Forming a Protection Film)

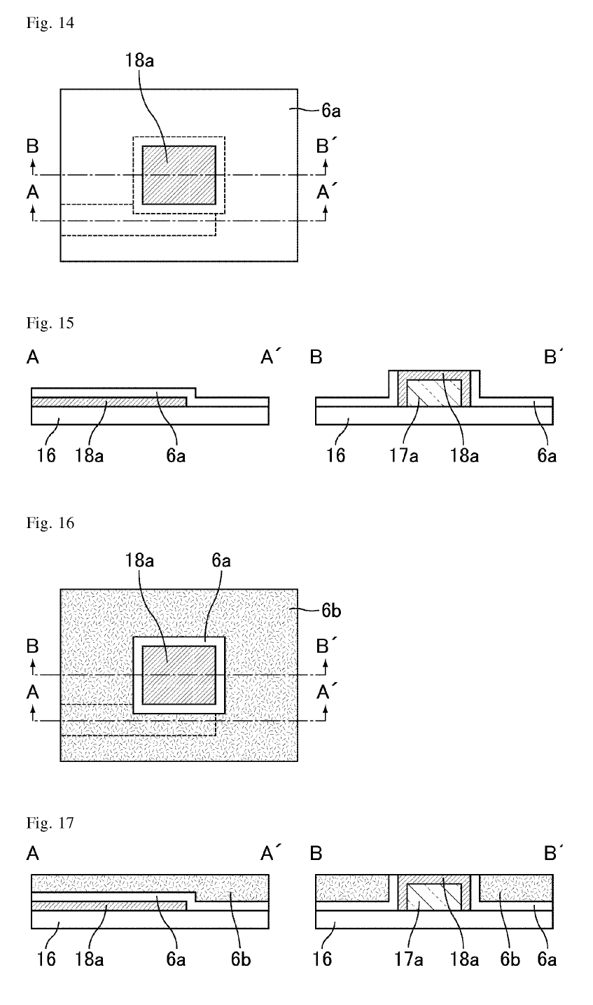

The step of forming a protection film in Embodiment 1 will be described referring to FIG. 14 and FIG. 15. FIG. 14 is a schematic plan view showing a state after the step of forming a protection film in Embodiment 1. FIG. 15 shows schematic cross-sectional views at A-A′ line and B-B′ line in FIG. 14. As shown in FIG. 14 and FIG. 15, a protection film 6a is formed using a chemical vapor deposition (CVD) apparatus to cover the conductive film 18a and the gate insulator 16. Then, a part of the protection film 6a is removed by dry etching to expose the conductive film 18a at a portion to be connected to a conductive film 18b (pixel electrode 14) which is to be formed in the subsequent steps. The protection film 6a is preferably an inorganic insulating film. The thickness of the protection film 6a is not particularly limited, and is preferably 400 nm or more but 600 nm or less.

### (Step of Forming a Flat Film)

The step of forming a flat film in Embodiment 1 will be described referring to FIG. 16 and FIG. 17. FIG. 16 is a schematic plan view showing a state after the step of forming a flat film in Embodiment 1. FIG. 17 shows schematic cross-sectional views at A-A′ line and B-B′ line in FIG. 16. As shown in FIG. 16 and FIG. 17, a flat film 6b is formed to cover the conductive film 18a and the protection film 6a using a coater and a baking apparatus. Then, a part of the flat film 6b is removed by ashing to expose the conductive film 18a at a portion to be connected to the conductive film 18b (pixel electrode 14) which is to be formed in the subsequent steps.

The flat film 6b is preferably an organic insulating film. The thickness of the flat film 6b is not particularly limited, and is preferably 1.5 μm or more but 2.5 μm or less.

### (Step of Forming a Conductive Film (Film for the Second Conductive Layer))

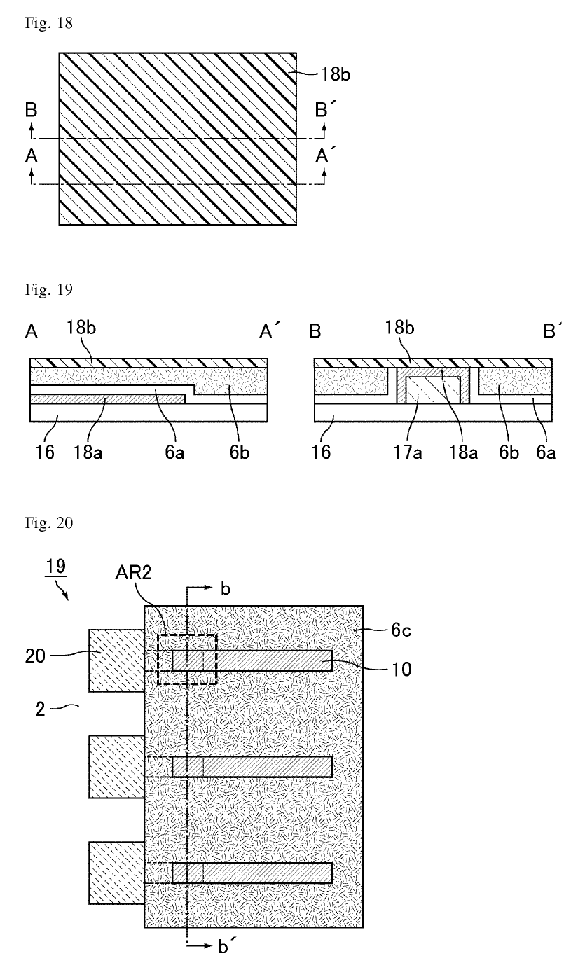

The step of forming a conductive film (film for the second conductive layer) in Embodiment 1 will be described referring to FIG. 18 and FIG. 19. FIG. 18 is a schematic plan view showing a state after the step of forming a conductive film (film for the second conductive layer) in Embodiment 1. FIG. 19 shows schematic cross-sectional views at A-A′ line and B-B′ line in FIG. 18. As shown in FIG. 18 and FIG. 19, the conductive film 18b is formed by sputtering on or above the conductive film 18a, the protection film 6a, and the flat film 6b on the side opposite to the glass substrate so as to be in contact with an exposed portion of the conductive film 18a. The conductive film 18b is to be made into a pixel electrode 14. The thickness of the conductive film 18b is not particularly limited, and is preferably 80 nm or more but 150 nm or less.

The conductive structure of Embodiment 1 can be produced as described above.

The method for producing a conductive structure of Embodiment 1 allows for production of a conductive structure in which the conductive film 18a (drain electrode 13) includes a protrusion (conductive film 18a formed on the upper side and side wall of the photoresist 17a) that is disposed in an opening provided in the protection film 6a and the flat film 6b, and the protrusion is connected directly to the conductive film 18b (pixel electrode 14). Thus, a method for producing a conductive structure can be provided which sufficiently prevents connection failure between the drain electrode 13 and the pixel electrode 14 regardless of the diameter and depth of the opening. The protrusion is in contact with an inner wall surface of the opening.

The conductive film 18a (drain electrode 13) and the conductive film 18b (pixel electrode 14) correspond to the first conductive layer and the second conductive layer, respectively, in one aspect of the present invention. The photoresist 17a corresponds to the photoresist in one aspect of the present invention. The protection film 6a and the flat film 6b correspond to the first insulating layer and the second insulating layer, respectively, in one aspect of the present invention. The step of forming a thick film photoresist, step of forming a conductive film (film for the first conductive layer), step of etching a conductive film (film for the first conductive layer), step of forming a protection film, step of forming a flat film, and step of forming a conductive film (film for the second conductive layer) respectively correspond to the steps (1), (2), (3), (4), (5), and (6) in one aspect of the present invention.

A display device of Embodiment 1 includes a thin film transistor array substrate including the conductive structure of Embodiment 1 and a counter substrate facing the thin film transistor array substrate.

An example of a conductive structure that was actually produced by the method of Embodiment 1 will be described below as Example 1.

### Example 1

The conductive structure of Example 1 has the following features: the photoresist 17a has a thickness of 2.0 μm; the conductive film. 18a is a stack of titanium (Ti), aluminum (Al), and titanium (Ti) in the stated sequence (hereinafter, also referred to as Ti/Al/Ti) and has a total thickness of 350 nm with Ti/Al/Ti=50 nm/200 nm/100 nm; the protection film 6a contains silicon nitride (SiNx) and has a thickness of 400 nm; the flat film 6b contains a coating-type acrylic material and has a thickness of 2.0 μm; and the conductive film 18b contains indium tin oxide (ITO) and has a thickness of 100 nm.

In the step of forming a thick film photoresist in Example 1, the baking was performed at a temperature of 220° C. for 50 minutes. The dry etching in the step of etching a conductive film (film for the first conductive layer) was performed using chlorine (Cl₂) gas and boron trichloride (BCl₃) gas at flow rates of Cl₂/BCl₃₌₁₀₀ sccm/300 sccm under a pressure of 1 Pa or higher but 2 Pa or lower with a radio frequency (RF) power of 1500 W. The ashing in the step of etching a conductive film (film for the first conductive layer) was performed using oxygen (O₂) gas at a flow rate of 1500 sccm under a pressure of 100 Pa with an RF power of 3000 W and a bias value of 500 W. The dry etching in the step of forming a protection film was performed using tetrafluoromethane (CF₄) gas and oxygen (O₂) gas at flow rates of CF₄/O₂=100 sccm/200 sccm under a pressure of 4 Pa or higher but 10 Pa or lower with an RF power of 1000 W. The ashing in the step of forming a flat film was performed using oxygen (O₂) gas at a flow rate of 1500 sccm under a pressure of 100 Pa with an RF power of 3000 W and a bias value of 500 W.

### Embodiment 2

In Embodiment 2, the conductive structure of the present invention is used to connect a terminal for connection to a source driver to a source bus line in a thin film transistor array substrate including a thin film transistor element.

The conductive structure of Embodiment 2 will be described referring to FIG. 20 and FIG. 21.

FIG. 20 is a schematic plan view showing a connection terminal of a thin film transistor array substrate which includes a conductive structure of Embodiment 2. As shown in FIG. 20, a source bus line 10 is extended from a terminal 20 for connection to a source driver in a connection terminal 19.

FIG. 21 shows a schematic cross-sectional view at b-b′ line in FIG. 20. As shown in FIG. 21, the connection terminal 19 includes a substrate 2 (for example, glass substrate); a terminal 20 for connection to a source driver provided on the main surface of the substrate 2; an insulating film 6c provided in a manner of covering the substrate 2 and the terminal 20 for connection to a source driver; and a source bus line 10 provided on the terminal 20 for connection to a source driver and the insulating film 6c so as to be in contact with an exposed portion of the terminal 20 for connection to a source driver, on the side opposite to the substrate 2 side of the terminal 20 for connection to a source driver and the insulating film 6c.

Moreover, as shown in FIG. 21, the terminal 20 for connection to a source driver includes a protrusion 4 that is disposed in an opening 7 provided in the insulating film 6c. The protrusion 4 is connected directly to the source bus line 10. Thus, connection failure between the terminal 20 for connection to a source driver and the source bus line 10 can be sufficiently prevented regardless of the diameter and depth of the opening 7. In FIG. 21, the protrusion 4 is in contact with an inner wall surface of the opening 7.

Preferably, the terminal 20 for connection to a source driver contains the same material as the gate bus line 9 as shown in FIG. 2 and FIG. 3 and includes a metal film. The metal film preferably contains molybdenum (Mo) or the like. The thickness of the terminal 20 for connection to a source driver is not particularly limited, and is preferably 150 nm or more but 300 nm or less.

The insulating film 6c may be either of an organic insulating film or an inorganic insulating film. The thickness of the insulating film 6c is not particularly limited, and is preferably 400 nm or more but 800 nm or less.

The source bus line 10 preferably includes a metal film. The metal film preferably contains titanium (Ti), aluminum (Al), or the like. The thickness of the source bus line 10 is not particularly limited, and is preferably 300 nm or more but 500 nm or less.

The diameter of the opening 7 is not particularly limited, and is preferably 1.0 μm or larger but 4.0 μm or smaller. The conductive structure of Embodiment 2 is particularly suitably used in the case where the opening 7 has a diameter of 2.0 μm or smaller. The depth (depth perpendicular to the main surface of the substrate 2) of the opening 7 is not particularly limited. The conductive structure of Embodiment 2 is particularly suitably used in the case where the opening 7 has a depth of 600 nm or more. The shape of the opening 7 is not particularly limited. The opening 7 may have a shape other than a columnar shape, for example, a rectangular parallelepiped shape. The diameter of the opening 7 may not only be the diameter of a circle or an ellipse but also be the length of a side of a square or a rectangle.

The height (height perpendicular to the main surface of the substrate 2) of the protrusion 4 is not particularly limited, and is preferably 0.6 μm or more but 4.0 μm or less. Although the height of the protrusion 4 is depicted to be the same as the depth of the opening 7 in FIG. 21, the height of the protrusion 4 may be different from the depth of the opening 7. The height of the protrusion 4 is preferably the same as the depth of the opening 7. The height of the protrusion 4 may be smaller or greater than the depth of the opening 7 as long as the protrusion 4 can be connected directly to the source bus line 10. The shape of the protrusion 4 is not particularly limited. The protrusion 4 may have a shape other than a columnar shape, for example, a rectangular parallelepiped shape.

The terminal 20 for connection to a source driver and the source bus line 10 correspond to the first conductive layer and the second conductive layer, respectively, in one aspect of the present invention. The insulating film 6c corresponds to the at least one insulating layer in one aspect of the present invention. The opening 7 provided in the insulating film 6c corresponds to the opening provided in the at least one insulating layer in one aspect of the present invention. The protrusion 4 corresponds to the protrusion in one aspect of the present invention.

The following will describe the method for producing a conductive structure of Embodiment 2. The conductive structure is used to connect the terminal 20 for connection to a source driver to the source bus line 10 at a site AR2 in FIG. 20.

The method for producing a conductive structure of Embodiment 2 includes a step of forming a thick film photoresist, a step of forming a conductive film (film for the first conductive layer), a step of forming a photoresist for patterning, a step of etching a conductive film (film for the first conductive layer), a photoresist-asking step, a step of forming an insulating film, and a step of forming a conductive film (film for the second conductive layer).

The following will describe the case where a conductive structure of Embodiment 2 is formed on the main surface of such a substrate 2 (for example, glass substrate) as shown in FIG. 22 and FIG. 23. FIG. 22 is a schematic plan view showing a substrate used in the production of a conductive structure of Embodiment 2. FIG. 23 shows schematic cross-sectional views at A-A′ line and B-B′ line in FIG. 22.

### (Step of Forming a Thick Film Photoresist)

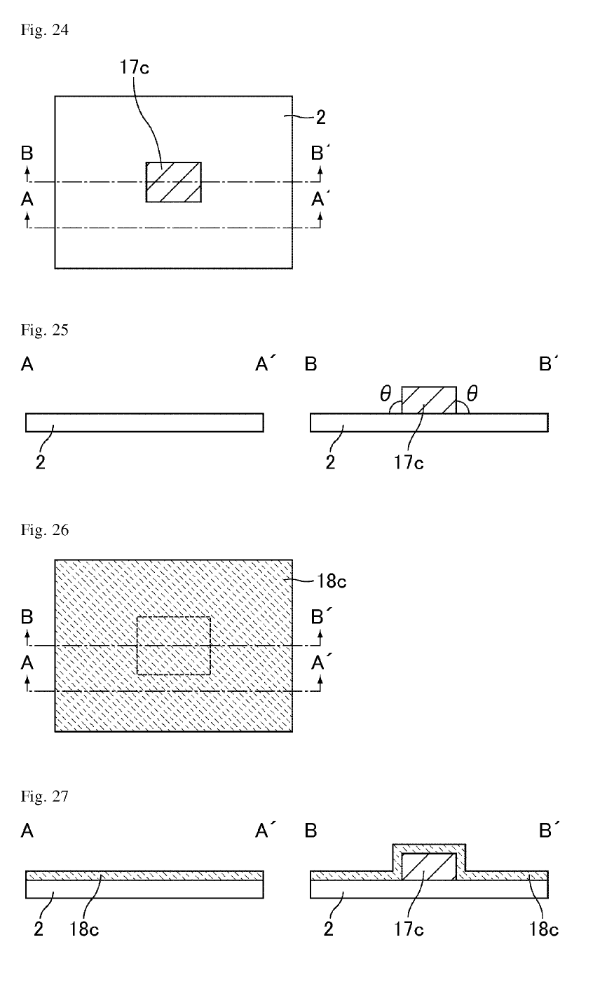

The step of forming a thick film photoresist in Embodiment 2 will be described referring to FIG. 24 and FIG. 25. FIG. 24 is a schematic plan view showing a state after the step of forming a thick film photoresist in Embodiment 2. FIG. 25 shows schematic cross-sectional views at A-A′ line and B-B′ line in FIG. 24. As shown in FIG. 24 and FIG. 25, a photoresist 17c is formed through application, exposure to light, development, and baking, on a part of the main surface of the substrate 2 to include a side wall that is perpendicular to the main surface of the substrate 2. The baking is performed to cure the photoresist. Desolvation of the photoresist 17c is suppressed, and the shape of the photoresist 17c is maintained due to subsequent film formation or the like on the photoresist 17c. The thickness of the photoresist 17c is not particularly limited, and is preferably 0.4 μm or more but 1.0 μm or less. The photoresist 17c as shown in FIG. 25 preferably has a taper angle θ (an angle between the main surface of the substrate 2 and the side wall of the photoresist 17c) of 85° or larger but 90° or smaller so that a film (for example, conductive film) to be formed on the side wall of the photoresist 17c in the subsequent steps remains after anisotropic etching. Use of a photoresist having a high contrast and high heat resistance allows for production of the photoresist 17c having the aforementioned taper angle θ.

### (Step of Forming a Conductive Film (Film for the First Conductive Layer))

The step of forming a conductive film (film for the first conductive layer) in Embodiment 2 will be described referring to FIG. 26 and FIG. 27. FIG. 26 is a schematic plan view showing a state after the step of forming a conductive film (film for the first conductive layer) in Embodiment 2. FIG. 27 shows schematic cross-sectional views at A-A′ line and B-B′ line in FIG. 26. As shown in FIG. 26 and FIG. 27, a conductive film 18c is formed by sputtering to cover the substrate 2 and the photoresist 17c. The conductive film 18c is to be made into the terminal 20 for connection to a source driver through subsequent steps. The conductive film 18c preferably includes a metal film. The metal film preferably contains molybdenum (Mo) or the like. The thickness of the conductive film 18c is not particularly limited, and is preferably 150 nm or more but 300 nm or less.

### (Step of Forming a Photoresist for Patterning)

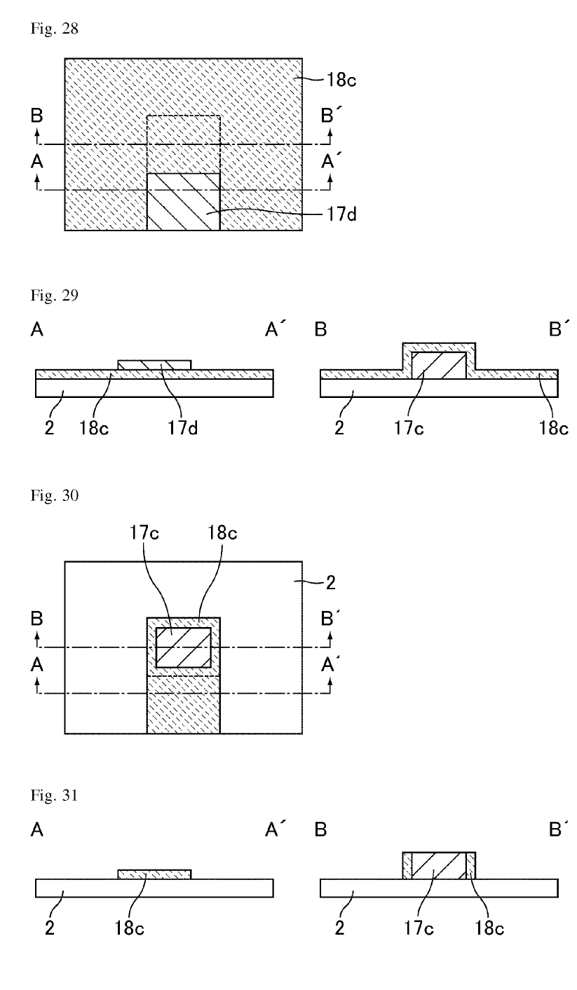

The step of forming a photoresist for patterning in Embodiment 2 will be described referring to FIG. 28 and FIG. 29. FIG. 28 is a schematic plan view showing a state after the step of forming a photoresist for patterning in Embodiment 2. FIG. 29 shows schematic cross-sectional views at A-A′ line and B-B′ line in FIG. 28. As shown in FIG. 28 and FIG. 29, a photoresist 17d is formed by photolithography on a part of the conductive film 18c on the side opposite to the substrate 2 side of the conductive film 18c so that the conductive film 18c is patterned into the shape of the terminal 20 for connection to a source driver. The photoresist 17d is not formed on the region overlapping the photoresist 17c and the conductive film 18c on the side wall of the photoresist 17c in a plan view of the main surface of the substrate 2 in FIG. 29.

### (Step of Etching a Conductive Film (Film for the First Conductive Layer))

The step of etching a conductive film (film for the first conductive layer) in Embodiment 2 will be described referring to FIG. 30 and FIG. 31. FIG. 30 is a schematic plan view showing a state after the step of etching a conductive film (film for the first conductive layer) in Embodiment 2. FIG. 31 shows schematic cross-sectional views at A-A′ line and B-B′ line in FIG. 30. As shown in FIG. 30 and FIG. 31, a part of the conductive film 18c which is not covered with the photoresist 17d and in parallel with the main surface of the substrate 2 is removed by anisotropic dry etching, and then the photoresist 17d is removed by ashing. As a result, the conductive film 18c remains at a part covered with the photoresist 17d and a part on the side wall of the photoresist 17c.

### (Photoresist-Ashing Step)

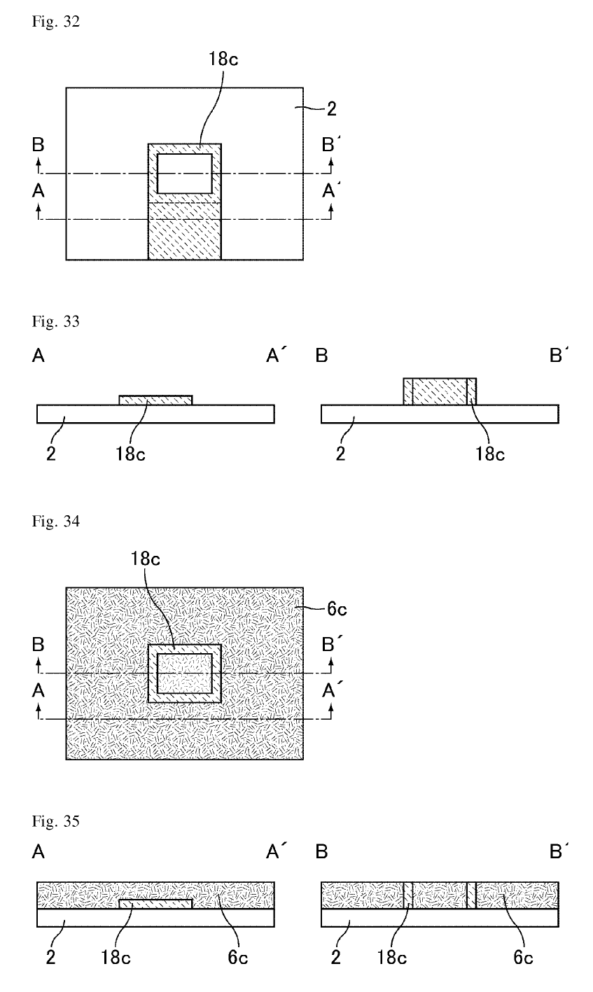

The photoresist-ashing step in Embodiment 2 will be described referring to FIG. 32 and FIG. 33. FIG. 32 is a schematic plan view showing a state after the photoresist-ashing step in Embodiment 2. FIG. 33 shows schematic cross-sectional views at A-A′ line and B-B′ line in FIG. 32. As shown in FIG. 32 and FIG. 33, the photoresist 17c is removed by ashing, which allows apart of the conductive film 18c to have a hollow quadrangular prism shape. As a result, a pattern of the terminal 20 for connection to a source driver is formed.

### (Step of Forming an Insulating Film)

The step of forming an insulating film in Embodiment 2 will be described referring to FIG. 34 and FIG. 35. FIG. 34 is a schematic plan view showing a state after the step of forming an insulating film in Embodiment 2. FIG. 35 shows schematic cross-sectional views at A-A′ line and B-B′ line in FIG. 34. As shown in FIG. 34 and FIG. 35, an insulating film 6c is formed using a CVD apparatus to cover the substrate 2 and the conductive film 18c. Then, a part of the insulating film 6c is removed by dry etching to expose the conductive film 18c at a portion to be connected to a conductive film 18d (source bus line 10) which is to be formed in the subsequent steps. The insulating film 6c may be either of an organic insulating film or an inorganic insulating film. The thickness of the insulating film 6c is not particularly limited, and is preferably 400 nm or more but 800 nm or less.

### (Step of Forming a Conductive Film (Film for the Second Conductive Layer))

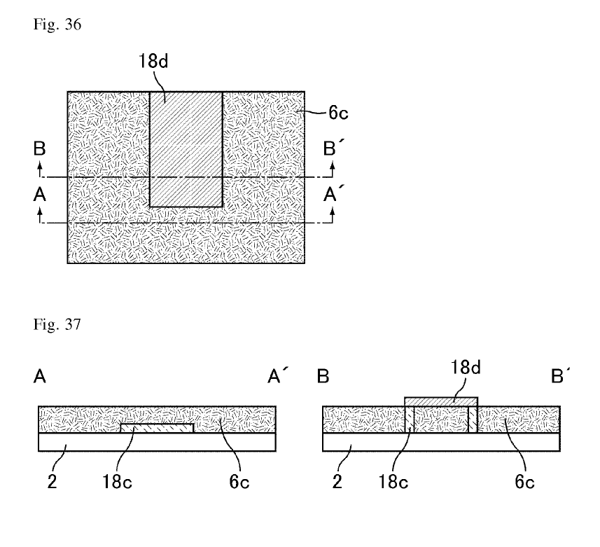

The step of forming a conductive film (film for the second conductive layer) in Embodiment 2 will be described referring to FIG. 36 and FIG. 37. FIG. 36 is a schematic plan view showing a state after the step of forming a conductive film (film for the second conductive layer) in Embodiment 2. FIG. 37 shows schematic cross-sectional views at A-A′ line and B-B′ line in FIG. 36. As shown in FIG. 36 and FIG. 37, the conductive film 18d is formed by sputtering on or above the conductive film 18c and the insulating film 6c on the side opposite to the substrate 2 so as to be in contact with an exposed portion of the conductive film 18c. The conductive film 18d is to be made into a source bus line 10. A photoresist (not shown) is formed by photolithography on a part of the conductive film 18d on the side opposite to the substrate 2 side of the conductive film 18d so that the conductive film 18d is patterned into the shape of the source bus line 10. Then, a part of the conductive film 18d which is not covered with the photoresist is removed by dry etching. As a result, a pattern of the conductive film 18d (source bus line 10) as shown in FIG. 36 and FIG. 37 is formed. The conductive film 18d preferably includes a metal film. The metal film preferably contains titanium (Ti), aluminum (Al), or the like. The thickness of the conductive film 18d is not particularly limited, and is preferably 300 nm or more but 500 nm or less.

The conductive structure of Embodiment 2 can be produced as described above.

The method for producing a conductive structure of Embodiment 2 allows for production of a conductive structure in which the conductive film 18c (terminal 20 for connection to a source driver) includes a protrusion (a part of the conductive film 18c formed on the side wall of the photoresist 17c and having a hollow quadrangular prism shape) that is disposed in an opening provided in the insulating film 6c, and the protrusion is connected directly to the conductive film. 18d (source bus line 10). Thus, a method for producing a conductive structure can be provided which sufficiently prevents connection failure between the terminal 20 for connection to a source driver and the source bus line 10 regardless of the diameter and depth of the opening. The protrusion is in contact with an inner wall surface of the opening.

The conductive film 18c (terminal 20 for connection to a source driver) and the conductive film 18d (source bus line 10) correspond to the first conductive layer and the second conductive layer, respectively, in one aspect of the present invention. The photoresist 17c corresponds to the photoresist in one aspect of the present invention. The insulating film 6c corresponds to the third insulating layer in one aspect of the present invention. The step of forming a thick film photoresist, step of forming a conductive film (film for the first conductive layer), step of etching a conductive film (film for the first conductive layer), photoresist-asking step, step of forming an insulating film, and step of forming a conductive film (film for the second conductive layer) respectively correspond to the steps (1), (2), (3), (7), (8), and (9) in one aspect of the present invention.

A display device of Embodiment 2 includes a thin film transistor array substrate including the conductive structure of Embodiment 2 and a counter substrate facing the thin film transistor array substrate.

An example of a conductive structure that was actually produced by the method of Embodiment 2 will be described below as Example 2.

### Example 2

The conductive structure of Example 2 has the following features: the photoresist 17c has a thickness of 0.4 μm; the conductive film 18c contains molybdenum (Mo) and has a thickness of 200 nm; the insulating film 6c contains silicon nitride (SiNx) and has a thickness of 600 nm; and the conductive film 18d is a Ti/Al/Ti stack and has a total thickness of 350 nm with Ti/Al/Ti=50 nm/200 nm/100 nm.

In the step of forming a thick film photoresist in Example 2, the baking was performed at a temperature of 220° C. for 50 minutes. The dry etching in the step of etching a conductive film (film for the first conductive layer) was performed using chlorine (Cl₂) gas at a flow rate of 200 sccm under a pressure of 1 Pa or higher but 2 Pa or lower with an RF power of 2000 W. The asking in the photoresist-asking step was performed using oxygen (O₂) gas at a flow rate of 1500 sccm under a pressure of 100 Pa with an RF power of 3000 W and a bias value of 500 W. The dry etching in the step of forming an insulating film was performed using tetrafluoromethane (CF₄) gas and oxygen (O₂) gas at flow rates of CF₄/O₂=100 sccm/200 sccm under a pressure of 4 Pa or higher but 10 Pa or lower with an RF power of 1000 W. The dry etching in the step of forming a conductive film (film for the second conductive layer) was performed using chlorine (Cl₂) gas and boron trichloride (BCl₃) gas at flow rates of Cl₂/BCl₃₌₁₀₀ sccm/300 sccm under a pressure of 1 Pa of higher but 2 Pa or lower with an RF power of 1500 W.

### Embodiment 3

In Embodiment 3, the conductive structure of the present invention is used to connect a pixel electrode of a thin film transistor array substrate to a counter electrode of a counter substrate which faces the thin film transistor array substrate in a liquid crystal display device.

The conductive structure of Embodiment 3 will be described referring to FIG. 38.

FIG. 38 is a schematic perspective view showing a liquid crystal display device which includes a conductive structure of Embodiment 3. As shown in FIG. 38, a liquid crystal display device 21a includes a thin film transistor array substrate 23 provided with a pixel electrode 14 on the outermost surface thereof; a counter substrate 24 that faces the thin film transistor array substrate 23 and includes a counter electrode 25; and a liquid crystal layer 22 sandwiched between those substrates.

Moreover, as shown in FIG. 38, the pixel electrode 14 includes a protrusion 4 that is disposed in an insulating layer including the liquid crystal layer 22, and the protrusion 4 is connected directly to the counter electrode 25. Thus, connection failure between the pixel electrode 14 and the counter electrode 25 can be sufficiently prevented. Further, the conductive structure of Embodiment 3 allows for suitable connection between the pixel electrode 14 and the counter electrode 25 without using conductive materials such as conductive paste or conductive beads which are usually used to electrically connect the pixel electrode 14 to the counter electrode 25.

The height (height in a direction perpendicular to the main surface of the thin film transistor array substrate 23) of the protrusion 4 of the pixel electrode 14 is preferably substantially the same as a cell gap (corresponding to the distance between the thin film transistor array substrate 23 and the counter substrate 24) in the liquid crystal display device 21a, and is more preferably the same as the cell gap in the liquid crystal display device 21a. The shape of the protrusion 4 is not particularly limited. The protrusion 4 may have a shape other than a columnar shape, for example, a rectangular parallelepiped shape.

The pixel electrode 14 and the counter electrode 25 correspond to the first conductive layer and the second conductive layer, respectively, in one aspect of the present invention. The liquid crystal layer 22 is included in the at least one insulating layer in one aspect of the present invention. A portion at which the protrusion 4 is disposed in the insulating layer including the liquid crystal layer 22 corresponds to the opening provided in the at least one insulating layer in one aspect of the present invention. The protrusion 4 corresponds to the protrusion in one aspect of the present invention.

The following will describe the method for producing a conductive structure of Embodiment 3. The conductive structure is used to connect the pixel electrode 14 to the counter electrode 25 in FIG. 38.

The method for producing a conductive structure of Embodiment 3 includes a step of forming a thick film photoresist, a step of forming a conductive film (film for the first conductive layer), a step of forming a photoresist for patterning, a step of etching a conductive film (film for the first conductive layer), and a step of bonding substrates. The method for producing a conductive structure of Embodiment 3 excluding the step of bonding substrates is the same as the method for producing a conductive structure of Embodiment 1, except that a pixel electrode 14 is formed instead of the drain electrode 13 in Embodiment 1.

### (Step of Forming a Thick Film Photoresist)

The step of forming a thick film photoresist in Embodiment 3 is the same as the step of forming a thick film photoresist in Embodiment 1, except that a thin film transistor array substrate 23 is formed instead of the substrate on which the gate insulator 16 is formed in Embodiment 1.

### (Step of Forming a Conductive Film (Film for the First Conductive Layer))

The step of forming a conductive film (film for the first conductive layer) in Embodiment 3 is the same as the step of forming a conductive film (film for the first conductive layer) in Embodiment 1, except that a material for the pixel electrode 14 (for example, preferably indium tin oxide (ITO) conductive film) is used to form the conductive film 18a in Embodiment 1.

### (Step of Forming a Photoresist for Patterning)

The step of forming a photoresist for patterning in Embodiment 3 is the same as the step of forming a photoresist for patterning in Embodiment 1.

### (Step of Etching a Conductive Film (Film for the First Conductive Layer))

The step of etching a conductive film (film for the first conductive layer) in Embodiment 3 is the same as the step of etching a conductive film (film for the first conductive layer) in Embodiment 1. A pattern of the pixel electrode 14 is formed in this step.

### (Step of Bonding Substrates)

The step of bonding substrates in Embodiment 3 will be described referring to FIG. 38. As shown in FIG. 38, the thin film transistor array substrate 23 provided with the pixel electrode 14 and the counter substrate 24 provided with the counter electrode 25 (corresponding to the conductive film 18b) which is formed by sputtering are bonded, so that the pixel electrode 14 is in contact with the counter electrode 25. The thickness of the counter electrode 25 is not particularly limited, and is preferably 80 nm or more but 150 nm or less.

The conductive structure of Embodiment 3 can be produced as described above.

The method for producing a conductive structure of Embodiment 3 allows for production of a conductive structure in which the pixel electrode 14 includes a protrusion 4 that is disposed in an insulating layer including the liquid crystal layer 22, and the protrusion 4 is connected directly to the counter electrode 25. Thus, a method for producing a conductive structure can be provided which sufficiently prevents connection failure between the pixel electrode 14 and the counter electrode 25. Further, the method for producing a conductive structure of Embodiment 3 allows for suitable connection between the pixel electrode 14 and the counter electrode 25 without using conductive materials such as conductive paste or conductive beads which are usually used to electrically connect the pixel electrode 14 to the counter electrode 25.

The conductive film 18a (pixel electrode 14) and the conductive film 18b (counter electrode 25) correspond to the first conductive layer and the second conductive layer, respectively, in one aspect of the present invention. The photoresist 17a corresponds to the photoresist in one aspect of the present invention. The thin film transistor array substrate 23 corresponds to the substrate in one aspect of the present invention. The counter substrate 24 corresponds to the counter substrate in one aspect of the present invention. The step of forming a thick film photoresist, step of forming a conductive film (film for the first conductive layer), step of etching a conductive film (film for the first conductive layer), and step of bonding substrates respectively correspond to the steps (1), (2), (3), and (10) in one aspect of the present invention.

A display device of Embodiment 3 is a liquid crystal display device including the conductive structure of Embodiment 3.

An example of a conductive structure that was actually produced by the method of Embodiment 3 will be described below as Example 3.

### Example 3

In Example 3, the thickness of the photoresist 17a is appropriately determined according to the cell gap in the liquid crystal display device 21a. The conductive films 18a and 18b each contain indium tin oxide (ITO) and have a thickness of 100 nm.

In the step of forming a thick film photoresist in Example 3, the baking was performed at a temperature of 220° C. for 50 minutes. The step of etching a conductive film (film for the first conductive layer) includes dipping in hydrochloric acid for 300 seconds. The resist used for the etching was removed by dipping in a peeling liquid for 600 seconds.

### Embodiment 4

In Embodiment 4, the conductive structure of the present invention is used to connect a pixel electrode of a thin film transistor array substrate to a counter electrode of a counter substrate which faces the thin film transistor array substrate in a liquid crystal display device.

The conductive structure of Embodiment 4 will be described referring to FIG. 39.

FIG. 39 is a schematic perspective view showing a liquid crystal display device which includes a conductive structure of Embodiment 4. As shown in FIG. 39, a liquid crystal display device 21b includes a thin film transistor array substrate 23 provided with a pixel electrode 14 on the outermost surface thereof; a counter substrate 24 that faces the thin film transistor array substrate 23 and includes a counter electrode 25; and a liquid crystal layer 22 sandwiched between those substrates.

Moreover, as shown in FIG. 39, the counter electrode 25 includes a protrusion 4 that is disposed in an insulating layer including the liquid crystal layer 22, and the protrusion 4 is connected directly to the pixel electrode 14. Thus, connection failure between the counter electrode 25 and the pixel electrode 14 can be sufficiently prevented. Further, the conductive structure of Embodiment 4 allows for suitable connection between the counter electrode 25 and the pixel electrode 14 without using conductive materials such as conductive paste or conductive beads which are usually used to electrically connect the counter electrode 25 to the pixel electrode 14.

The height (height in a direction perpendicular to the main surface of the counter substrate 24) of the protrusion 4 of the counter electrode 25 is preferably substantially the same as a cell gap (corresponding to the distance between the thin film transistor array substrate 23 and the counter substrate 24) in the liquid crystal display device 21b, and is more preferably the same as the cell gap in the liquid crystal display device 21b. The shape of the protrusion 4 is not particularly limited. The protrusion 4 may have a shape other than a columnar shape, for example, a rectangular parallelepiped shape.

The counter electrode 25 and the pixel electrode 14 correspond to the first conductive layer and the second conductive layer, respectively, in one aspect of the present invention. The liquid crystal layer 22 is included in the at least one insulating layer in one aspect of the present invention. A portion at which the protrusion 4 is disposed in the insulating layer including the liquid crystal layer 22 corresponds to the opening provided in the at least one insulating layer in one aspect of the present invention. The protrusion 4 corresponds to the protrusion in one aspect of the present invention.

The following will describe the method for producing a conductive structure of Embodiment 4. The conductive structure is used to connect the counter electrode 25 to the pixel electrode 14 in FIG. 39.

The method for producing a conductive structure of Embodiment 4 includes a step of forming a thick film photoresist, a step of forming a conductive film (film for the first conductive layer), a step of forming a photoresist for patterning, a step of etching a conductive film (film for the first conductive layer), and a step of bonding substrates. The method for producing a conductive structure of Embodiment 4 is the same as the method for producing a conductive structure of Embodiment 3, except that a counter electrode 25 and a pixel electrode 14 are formed instead of the pixel electrode 14 and the counter electrode 25, respectively, in Embodiment 3.

The conductive structure of Embodiment 4 can be produced as described above.

The method for producing a conductive structure of Embodiment 4 allows for production of a conductive structure in which the counter electrode 25 includes a protrusion 4 that is disposed in an insulating layer including the liquid crystal layer 22, and the protrusion 4 is connected directly to the pixel electrode 14. Thus, a method for producing a conductive structure can be provided which sufficiently prevents connection failure between the counter electrode 25 and the pixel electrode 14. Further, the method for producing a conductive structure of Embodiment 4 allows for suitable connection between the counter electrode 25 and the pixel electrode 14 without using conductive materials such as conductive paste or conductive beads which are usually used to electrically connect the counter electrode 25 to the pixel electrode 14.

The conductive film 18a (counter electrode 25) and the conductive film 18b (pixel electrode 14) correspond to the first conductive layer and the second conductive layer, respectively, in one aspect of the present invention. The photoresist 17a corresponds to the photoresist in one aspect of the present invention. The counter substrate 24 corresponds to the substrate in one aspect of the present invention. The thin film transistor array substrate 23 corresponds to the counter substrate in one aspect of the present invention. The step of forming a thick film photoresist, step of forming a conductive film (film for the first conductive layer), step of etching a conductive film (film for the first conductive layer), and step of bonding substrates respectively correspond to the steps (1), (2), (3), and (10) in one aspect of the present invention.

A display device of Embodiment 4 is a liquid crystal display device including the conductive structure of Embodiment 4.

An example of a conductive structure that was actually produced by the method of Embodiment 4 will be described below as Example 4.

### Example 4

In Example 4, the thickness of the photoresist 17a is appropriately determined according to the cell gap in the liquid crystal display device 21b. The conductive films 18a and 18b each contain indium tin oxide (ITO) and have a thickness of 100 nm.

In the step of forming a thick film photoresist in Example 4, the baking was performed at a temperature of 220° C. for 50 minutes. The step of etching a conductive film (film for the first conductive layer) includes dipping in hydrochloric acid for 300 seconds. The resist used for the etching was removed by dipping in a peeling liquid for 600 seconds.

### Other Preferable Embodiments

In addition to the aforementioned liquid crystal display devices, examples of the display devices according to the embodiments include a display device using microelectromechanical systems (MEMS) technology, such as a MEMS shutter display. The conductive structure of the present invention is suitably used to electrically connect a drive circuit of the MEMS shutter display to an MEMS actuator which can be driven by a voltage applied from the drive circuit. In the MEMS shutter display, each pixel includes a micro shutter produced using MEMS technology. The amount of transmission of light from a light source, such as a back light, is controlled by opening and closing the shutter so as to switch on and off the display. The MEMS shutter display does not require any polarizing plate and color filter which are necessary in current mainstream liquid crystal displays. Thus, the MEMS shutter display can highly efficiently use light from a light source such as aback light and can save the electric power consumption.

### Comparative Embodiment 1

In Comparative Embodiment 1, a conventional conductive structure is used to connect a drain electrode to a pixel electrode in a thin film transistor array substrate including a thin film transistor element.

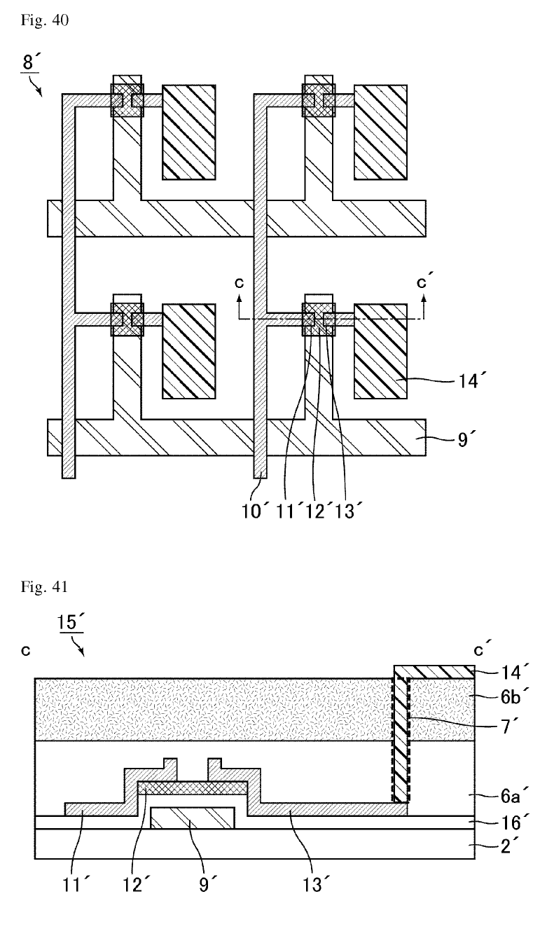

The conductive structure of Comparative Embodiment 1 will be described referring to FIG. 40 and FIG. 41.

FIG. 40 is a schematic plan view showing a pixel portion of a thin film transistor array substrate which includes a conductive structure of Comparative Embodiment 1. In a pixel portion 8′ shown in FIG. 40, a voltage supplied from a source bus line 10′ is applied through a source electrode 11′, a semiconductor layer 12′, and a drain electrode 13′ to a pixel electrode 14′ at the timing when a pixel is selected by a gate bus line 9′.

FIG. 41 shows a schematic cross-sectional view at c-c′ line in FIG. 40. As shown in FIG. 41, a thin film transistor element 15′ of the thin film transistor array substrate includes a substrate 2′ (for example, glass substrate); a gate bus line 9′ provided on the main surface of the substrate 2′; a gate insulator 16′ provided in a manner of covering the gate bus line 9′; a semiconductor layer 12′ provided on a part of the gate insulator 16′ at a position overlapped with the gate bus line 9′ in a plan view of the main surface of the substrate 2′; a source electrode 11′ provided on a part of the gate insulator 16′ and a part of the semiconductor layer 12′ on the side opposite to the substrate 2′ side of the gate insulator 16′ and the semiconductor layer 12′; a drain electrode 13′ provided on a part of the gate insulator 16′ and a part of the semiconductor layer 12′ on the side opposite to the substrate 2′ side of the gate insulator 16′ and the semiconductor layer 12′; a protection film 6a′ provided in a manner of covering the gate insulator 16′, the semiconductor layer 12′, the source electrode 11′, and the drain electrode 13′; a flat film 6b′ provided on the protection film 6a′ on the side opposite to the substrate 2′ side of the protection film 6a′; and a pixel electrode 14′ provided on the flat film 6b′ on the side opposite to the substrate 2′ side of the flat film 6b′.

In Comparative Embodiment 1, an opening 7′ (contact hole) is formed in the protection film 6a′ and the flat film 6b′ by subjecting these films to treatments such as photolithography and etching as shown in FIG. 41. Next, the pixel electrode 14′ is formed by sputtering on the flat film 6b′ on the side opposite to the substrate 2′ side of the flat film 6b′ to fill the opening 7′, so that the pixel electrode 14′ is connected to the drain electrode 13′. In the case where the opening 7′ has a small diameter and is deep, the opening 7′ cannot be sufficiently filled with the pixel electrode 14′, whereby causing connection failure between the drain electrode 13′ and the pixel electrode 14′. Thus, connection failure between the drain electrode 13′ and the pixel electrode 14′ cannot be sufficiently prevented regardless of the diameter and depth of the opening 7′.

### Comparative Embodiment 2

In Comparative Embodiment 2, a conventional conductive structure is used to connect a terminal for connection to a source driver to a source bus line in a thin film transistor array substrate including a thin film transistor element.

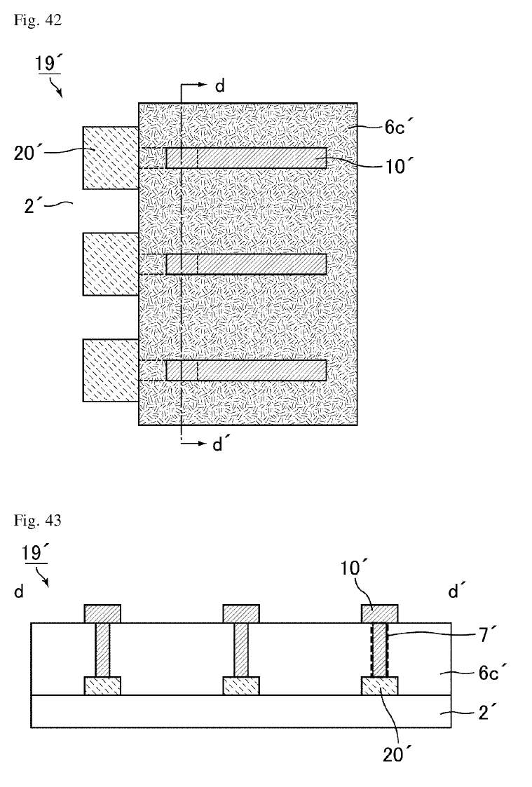

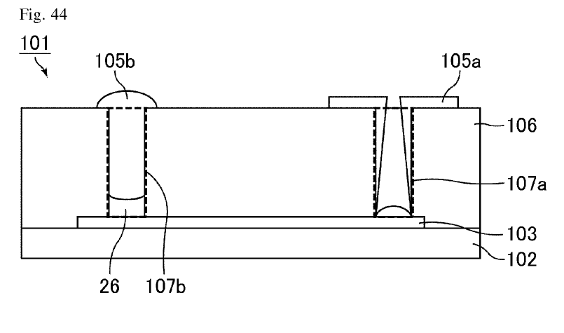

The conductive structure of Comparative Embodiment 2 will be described referring to FIG. 42 and FIG. 43.

FIG. 42 is a schematic plan view showing a connection terminal of a thin film transistor array substrate which includes a conductive structure of Comparative Embodiment 2.

As shown in FIG. 42, a source bus line 10′ is extended from a terminal 20′ for connection to a source driver in a connection terminal 19′.

FIG. 43 shows a schematic cross-sectional view at d-d′ line in FIG. 42. As shown in FIG. 43, the connection terminal 19′ includes a substrate 2′ (for example, glass substrate); the terminal 20′ for connection to a source driver provided on the main surface of the substrate 2′; an insulating film 6c′ provided in a manner of covering the substrate 2′ and the terminal 20′ for connection to a source driver; and the source bus line 10′ provided on the insulating film 6c′ on the side opposite to the substrate 2′ side of the insulating film 6c′.

In Comparative Embodiment 2, an opening 7′ (contact hole) is formed in the insulating film 6c′ by subjecting the film to treatments such as photolithography and etching as shown in FIG. 43. Next, a film for forming the source bus line 10′ is formed by sputtering on the insulating film 6c′ on the side opposite to the substrate 2′ side of the insulating film 6c′ to fill the opening 7′, so that the film is connected to the terminal 20′ for connection to a source driver. In the case where the opening 7′ has a small diameter and is deep, the opening 7′ cannot be sufficiently filled with the film for forming the source bus line 10′, whereby causing connection failure between the terminal 20′ for connection to a source driver and the source bus line 10′. Thus, connection failure between the terminal 20′ for connection to a source driver and the source bus line 10′ cannot be sufficiently prevented regardless of the diameter and depth of the opening 7′.

### REFERENCE SIGNS LIST

1, 101: conductive structure
2, 2′, 102: substrate
3, 103: first conductive layer
4: protrusion
5, 105a, 105b: second conductive layer
6, 106: insulating layer
6a, 6a′: protection film
6b, 6b′: flat film
6c, 6c′: insulating film
7, 7′: opening
8, 8′: pixel portion
9, 9′: gate bus line
10, 10′: source bus line
11, 11′: source electrode
12, 12′: semiconductor layer
13, 13′: drain electrode
14, 14′: pixel electrode
15, 15′: thin film transistor element
16, 16′: gate insulator
17a, 17b, 17c, 17d: photoresist
18a, 18b, 18c, 18d: conductive film
19, 19′: connection terminal
20, 20′: terminal for connection to a source driver
21a, 21b: liquid crystal display device
22: liquid crystal layer
23: thin film transistor array substrate
24: counter substrate
25: counter electrode
26: air
107a, 107b: contact hole

1: A conductive structure comprising, in the following sequence:
a first conductive layer,
at least one insulating layer, and
a second conductive layer electrically connected to the first conductive layer,
the first conductive layer including a protrusion that is disposed in an opening provided in the at least one insulating layer and is connected directly to the second conductive layer.

2: The conductive structure according to claim 1,
wherein the first conductive layer serves as a drain electrode, and
the second conductive layer serves as a pixel electrode.

3: The conductive structure according to claim 1,
wherein the first conductive layer serves as a terminal for connection to a source driver, and
the second conductive layer serves as a source bus line.

4: The conductive structure according to claim 1,
wherein the first conductive layer serves as a pixel electrode,
the second conductive layer serves as a counter electrode, and
the at least one insulating layer includes a liquid crystal layer.

5: The conductive structure according to claim 1,
wherein the first conductive layer serves as a counter electrode,
the second conductive layer serves as a pixel electrode, and
the at least one insulating layer includes a liquid crystal layer.

6: A method for producing a conductive structure comprising, in the following sequence, a first conductive layer, at least one insulating layer, and a second conductive layer electrically connected to the first conductive layer,
the method comprising the steps of:
(1) forming, on a main surface of a substrate, a photoresist including a side wall that is perpendicular to the main surface of the substrate,
(2) forming a film for the first conductive layer to cover the photoresist, and
(3) anisotropically etching the film for the first conductive layer so that at least the portion of the first conductive layer on the side wall of the photoresist remains.

7: The method for producing a conductive structure according to claim 6,
wherein the at least one insulating layer includes a first insulating layer and a second insulating layer, and
the step (3) is followed by the steps of:
(4) forming the first insulating layer to cover the first conductive layer and then creating an opening in the first insulating layer to expose the first conductive layer at a portion to be connected to the second conductive layer,
(5) forming the second insulating layer to cover the first conductive layer and the first insulating layer and then creating an opening in the second insulating layer to expose the first conductive layer at the portion to be connected to the second conductive layer, and
(6) forming the second conductive layer on the side opposite to the substrate and on or above the first conductive layer, the first insulating layer, and the second insulating layer, so that the second conductive layer is connected to the exposed portion of the first conductive layer.

8: The method for producing a conductive structure according to claim 6,
wherein the at least one insulating layer includes a third insulating layer, and
the step (3) is followed by the steps of:
(7) removing the photoresist,
(8) forming the third insulating layer to cover the first conductive layer and then creating an opening in the third insulating layer to expose the first conductive layer at a portion to be connected to the second conductive layer, and
(9) forming the second conductive layer on the side opposite to the substrate and on or above the first conductive layer and the third insulating layer, so that the second conductive layer is connected to the exposed portion of the first conductive layer.

9: The method for producing a conductive structure according to claim 6,
wherein the step (3) is followed by the step of:
(10) bonding the substrate provided with the first conductive layer and a counter substrate provided with the second conductive layer so that the first conductive layer is connected to the second conductive layer.

10: The method for producing a conductive structure according to claim 7,
wherein the first conductive layer serves as a drain electrode, and
the second conductive layer serves as a pixel electrode.

11: The method for producing a conductive structure according to claim 8,
wherein the first conductive layer serves as a terminal for connection to a source driver, and
the second conductive layer serves as a source bus line.

12: The method for producing a conductive structure according to claim 9,
wherein the first conductive layer serves as a pixel electrode,
the second conductive layer serves as a counter electrode, and
the at least one insulating layer includes a liquid crystal layer.

13: The method for producing a conductive structure according to claim 9,
wherein the first conductive layer serves as a counter electrode,
the second conductive layer serves as a pixel electrode, and
the at least one insulating layer includes a liquid crystal layer.

14: A display device comprising the conductive structure according to claim 1.
